(19) United States
(12) Patent Application Publication
(10) Pub. No.: US 2024/0003338 A1
(43) Pub. Date: Jan. 4, 2024

(54) ROLLER BEARING

(71) Applicant: NTN CORPORATION, OSAKA (JP)

(72) Inventors: Yuusaku KIBA, Kuwana-shi (JP); Kazumasa SEKO, Kuwana-shi (JP); Michio HORI, Kuwana-shi (JP); Koji MIYAKE, Kyoto-shi (JP); Yoshikazu TANAKA, Kyoto-shi (JP)

(73) Assignee: NTN CORPORATION, OSAKA (JP)

(21) Appl. No.: 18/369,910

(22) Filed: Sep. 19, 2023

Related U.S. Application Data
(63) Continuation of application No. PCT/JP2022/011557, filed on Mar. 15, 2022.

(30) Foreign Application Priority Data
Mar. 22, 2021 (JP) 2021-047039

(51) Int. Cl. F03D 80/70

(52) U.S. Cl. CPC F03D 80/703; F05B 2240/54; F05B 2280/2006; F05B 2280/6011

(57) ABSTRACT

A roller bearing includes: inner and outer rings; rollers interposed between raceway surfaces of the inner and outer rings and having a roller outer circumferential surface; a cage retaining the rollers; and a DLC film on the roller outer circumferential surface. The DLC film includes a superficial layer having cavities provided therein to hold a lubricating agent. The rollers have a ratio of surface area occupied by the cavities of 40% or less, and the cavities have a size of 10 to 100 μm when viewed in a plan view thereof. The DLC film can have a multilayered structure in which the superficial layer is layered on an additional layer, and the cavities can include a void of soft DLC present in the superficial layer and having a film hardness lower than that of the additional layer.

### CROSS REFERENCE TO THE RELATED APPLICATION

This application is a continuation application, under 35 U.S.C. § 111(a) of international patent application No. PCT/JP2022/011557, filed Mar. 15, 2022, which claims priority to Japanese patent application No. 2021-047039, filed Mar. 22, 2021, the entire disclosure of all of which are herein incorporated by reference as a part of this application.

### BACKGROUND OF THE INVENTION

### Field of the Invention

The present invention relates to a roller bearing and is directed to a technology employed in, for example, a self-aligning roller bearing used for the support of a main shaft of a wind turbine generator.

### Description of Related Art

It is conventionally practiced to apply a metallic coating film such as a diamond-like carbon (DLC) film on a selected part of a bearing and additionally provide a surface of the DLC film with a feature of minute irregularities having a center line average roughness Ra of 0.01 to 0.2 μm to achieve an improved lubricating performance (Patent Document 1). Such a feature of irregularities can be imparted to a DLC film by making deliberate adjustments to the conditions under which the DLC film is to be deposited or by striking a surface of the DLC film with fine particles by, for example, a shot peening process.

### RELATED DOCUMENT

### Patent Document

[Patent Document 1] JP Laid-open Patent Publication No. 2010-126419

An instance is considered in which a feature of minute irregularities is imparted to a DLC film. In a lubricated environment, the feature of irregularities present in a surface of the DLC film serves as dimples for holding oil to help achieve an improved lubricating performance. Yet, there is a room for improvement in such a feature of minute irregularities, as shown in Patent Document 1, in terms of the force with which to hold a lubricating agent. In particular, it faces a challenge in achieving an improved lubricating performance in a less lubricated situation or a lightly lubricated environment.

### SUMMARY OF THE INVENTION

An object of the present invention is to provide a roller bearing which can achieve an improved lubricating performance in a less lubricated situation or a lightly lubricated environment.

The present invention provides a roller bearing which includes: inner and outer rings; rollers interposed between raceway surfaces of the inner and outer rings and having a roller outer circumferential surface; a cage retaining the rollers; and a DLC film on the roller outer circumferential surface. The DLC film includes a superficial layer having cavities provided therein to hold a lubricating agent. The rollers have a ratio of surface area occupied by the cavities of 40% or less. The cavities have a size of 10 to 100 μm when viewed in a plan view thereof.

The “ratio of surface area” in this context refers to a ratio of surface area occupied by the cavities on the entire surface area of the outer circumferential surface of a roller.

The cavities provided in the superficial layer of the DLC film according to this configuration with a size of between more than 10 μm and less than 100 μm can serve as so-called, oil reservoir dimples in which the lubricating agent is held, to thereby help improve the ability of the lubricating agent to form oil films and, therefore, help achieve an improved lubricating performance in a less lubricated situation or a lightly lubricated environment. In addition, by selecting the ratio of surface area occupied by the cavities to be 40% or less, the DLC film can keep its durability and can thereby prevent delamination of the superficial layer from the DLC film.

The DLC film may have a multilayered structure in which the superficial layer is layered on an additional layer, and the cavities may include a void of soft DLC present in the superficial layer and having a film hardness lower than that of the additional layer. The Applicant has discovered that, after the DLC film has been deposited, segments of soft DLC having a film hardness lower than that/those of the additional layer(s) or remaining layer(s) are scattered at the top of the superficial layer. This makes it possible to form the aforementioned cavities with ease by removing the soft DLC present at the top of the superficial layer in, for example, a lapping process. In this way, the cavities can be formed without changing the deposition conditions for the DLC film itself, thereby preventing possible deteriorations in the properties of the DLC film. Furthermore, the cavities can be formed without using fine particles provided specifically for this purpose as in a shot peening process, thereby enabling the manufacturing cost to be reduced.

The DLC film may have a trilayered structure of a metal layer or a layer of a metal, a mixed layer of the metal and DLC as an intermediate layer, and the superficial layer, in the stated order starting from a side adjacent to a base material of the rollers. In this way, it is possible to avoid abrupt changes in the physical properties such as a hardness and an elastic modulus within the DLC film, thereby improving the adhesion of the DLC film to the rollers.

The roller bearing may further include a DLC film on at least one of the raceway surface of the inner ring or the raceway surface of the outer ring: the DLC film may include a superficial layer having cavities provided therein to hold the lubricating agent; the raceway surface or raceway surfaces may have a ratio of surface area occupied by the cavities of 40% or less; and the cavities may have a size of 10 to 100 μm when viewed in a plan view thereof.

The “ratio of surface area” in this context refers to a ratio of surface area occupied by the cavities on the entire surface area of a respective one of the raceway surface(s).

The cavities provided in the superficial layer of the DLC film on respective one(s) of the raceway surfaces according to this configuration with a size of 10 to 100 μm can also serve as so-called, oil reservoir dimples in which the lubricating agent is held. Thus, a further improved lubricating performance can be achieved thanks to the combined effect with the lubricant agent held in the cavities provided in the DLC film on the rollers.

The roller bearing may be a self-aligning roller bearing configured to support a main shaft of a wind turbine generator. In this way, a self-aligning roller bearing for use in a wind turbine generator can be produced which has a prolonged service life and excellent maintainability.

Any combinations of at least two features disclosed in the claims and/or the specification and/or the drawings should also be construed as encompassed by the present invention. Especially, any combinations of two or more of the claims should also be construed as encompassed by the present invention.

### BRIEF DESCRIPTION OF THE DRAWINGS

The present invention will be more clearly understood from the following description of preferred embodiments made by referring to the accompanying drawings. However, the embodiments and the drawings are given merely for the purpose of illustration and explanation, and should not be used to delimit the scope of the present invention, which scope is to be delimited by the appended claims. In the accompanying drawings, alike symbols indicate alike or corresponding parts throughout the different figures, and:

FIG. 1 shows a longitudinal cross section of a self-aligning roller bearing, in accordance with a first embodiment of the present invention;

FIG. 2 is a diagram that illustrates asymmetrical rollers in the self-aligning roller bearing;

FIG. 3A shows a cross sectional view which illustrates the schematic configuration of a DLC film deposited on a roller outer circumferential surface in the self-aligning roller bearing;

FIG. 3B shows a cross sectional view which illustrates how cavities are provided in a superficial layer of the DLC film;

FIG. 4 shows a fragmentary enlarged view of the portion IV in FIG. 3B;

FIG. 5 shows a fragmentary enlarged plan view of the cavities in the DLC film;

FIG. 6 shows a cross sectional view which schematically illustrates how a DLC film is provided on a raceway surface in a self-aligning roller bearing, in accordance with another embodiment of the present invention;

FIG. 7 shows a longitudinal cross section of a self-aligning roller bearing, in accordance with yet another embodiment of the present invention;

FIG. 8 shows a perspective view of a relevant portion of an example main shaft support assembly for a wind turbine generator;

FIG. 9 shows a cutaway side view of the relevant portion of the main shaft support assembly; and

FIG. 10 shows a schematic diagram of a test machine.

### DESCRIPTION OF EMBODIMENTS

### First Embodiment

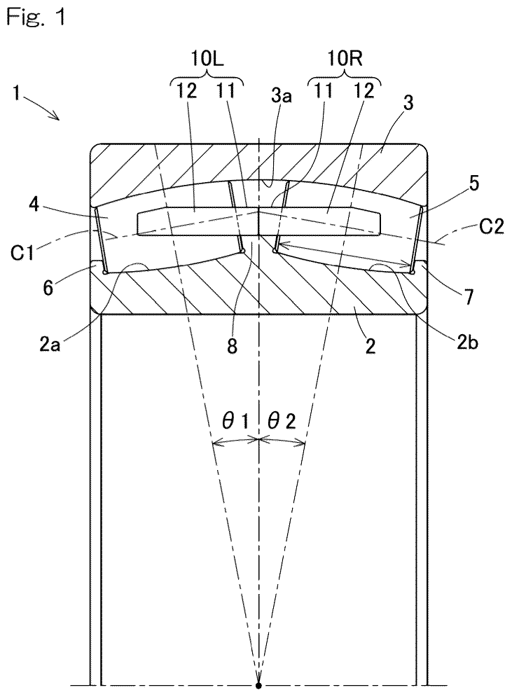

An example self-aligning roller bearing employing a roller bearing according to the present invention will be described in connection with FIGS. 1 to 5. The following discussion also contains reference to a process for producing a DLC film.

As illustrated in FIG. 1, the self-aligning roller bearing 1 includes inner and outer rings 2, 3, a double row of left and right rollers 4, 5 or left and right rows of rollers 4, 5 interposed between raceway surfaces of the inner and outer rings 2, 3, and cages 10L, 10R retaining the rollers 4, 5. The double row of left and right rollers 4, 5 are situated between the inner ring 2 and the outer ring 3 in an aligned manner along a width direction, i.e., an axial direction, of the bearing. The raceway surface 3a of the outer ring 3 has a spherical shape.

The rollers 4, 5 in each of the left and right rows have a roller outer circumferential surface with a cross sectional shape whose contour runs along the raceway surface 3a of the outer ring 3. In other words, the roller outer circumferential surface for the rollers 4, 5 is described by a curved surface formed by a solid of revolution which is generated by rotating a partial arc defining the raceway surface 3a of the outer ring 3 about a respective one of centerlines C1, C2 of the rollers 4, 5. The inner ring 2 has a double row of raceway surfaces 2a, 2b formed thereon with a cross sectional shape whose contour runs along the roller outer circumferential surface for the respective rows of left and right rollers 4, 5. The outer circumferential surface of the inner ring 2 has opposite ends that are provided with respective small collars 6, 7. The outer circumferential surface of the inner ring 2 has a central portion that is provided with a central collar 8 which is sandwiched between the left and right rollers 4, 5.

Each row of the rollers 4, 5, the inner ring 2, and the outer ring 3 are made from a ferrous material. Any type of steel that is commonly used as the ferrous material can be employed, for instance. Examples include high carbon chromium bearing steel, carbon steel, tool steel, martensitic stainless steel, and carburized steel.

The instant embodiment is directed to an example application involving a self-aligning roller bearing 1 with a symmetric design of left and right rows having the same left row and right row contact angles θ1, θ2. The terms “left” and “right” are used herein only for convenience, in order to describe the relative positions and relations between different elements of the bearing in an axial direction thereof. The terms “left” and “right” used herein coincide with the left and the right in each figure of the drawings, for a better understanding of the present invention.

The rollers 4, 5 in each of the left and right rows are retained by a respective one of the cages 10L, 10R. The left row cage 10L includes an annular section 11 and a plurality of pillar sections 12 axially extending from the annular section 11 towards one side (i.e., a left-hand side) so as to define pockets between the pillar sections 12 in which the left row of the rollers 4 is retained. The right row cage 10R includes an annular section 11 and a plurality of pillar sections 12 axially extending from the annular section 11 towards the other side (i.e., a right-hand side) so as to define pockets between the pillar sections 12 in which the right row of the rollers 5 is retained.

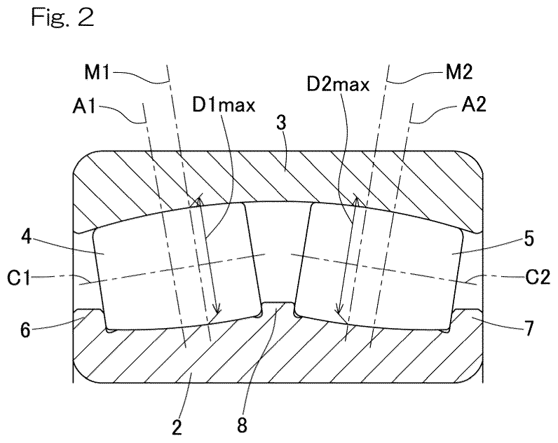

As illustrated in FIG. 2, the rollers 4, 5 in each of the left and right rows are composed of asymmetrical rollers, each having a maximum roller diameter D1max, D2max at a position M1, M2 which is offset from a roller length mid-position A1, A2. The position at which a roller 4 in the left row has the maximum roller diameter D1max is situated on the right-hand side of the roller length mid-position A1, while the position at which a roller 5 in the right row has the maximum roller diameter D2max is situated on the left-hand side of the roller length mid-position A2. Each row of the left and right rollers 4, 5 composed of such asymmetrical rollers gives rise to the generation of an induced thrust load. The aforementioned central collar 8 of the inner ring 2 is provided to bear the induced thrust load. The combination of the asymmetrical rollers 4, 5 and the central collar 8 facilitates the three-point guiding of the rollers 4, 5 by the inner ring 2, the outer ring 3, and the central collar 8, thereby resulting in a better guiding accuracy.

<DLC Film>

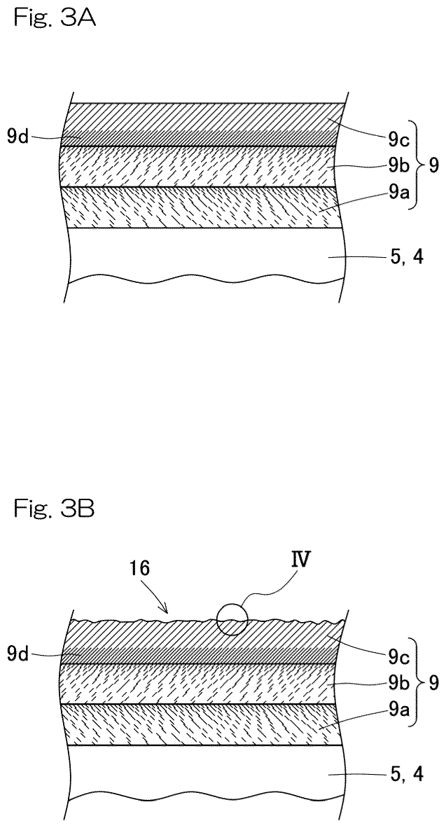

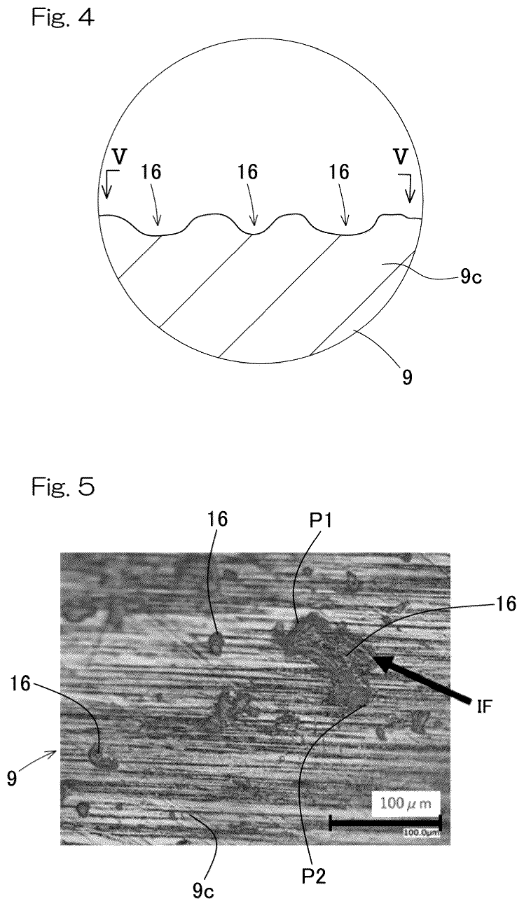

A diamond-like carbon (DLC) film having a multilayered structure is provided on the roller outer circumferential surface for each row of the rollers 4, 5 shown in FIG. 1. The DLC film has a multilayered structure in which a superficial layer is layered on an additional layer. In particular, as illustrated in FIG. 3A, the DLC film 9 in the instant example has a trilayered structure of a metal layer 9a or a layer of a metal, a mixed layer of the metal and DLC as an intermediate layer 9b, and a superficial layer 9c, in the stated order starting from a side adjacent to a base material of the rollers 4, 5. As illustrated in FIG. 4, the superficial layer 9c of the DLC film 9 has cavities 16 provided therein to hold a lubricating agent.

FIG. 5 shows a fragmentary enlarged plan view of the cavities 16 in the DLC film 9, as viewed along the arrows V-V of FIG. 4. As illustrated in FIG. 5, the rollers 4, 5 have a ratio of surface area occupied by the cavities 16 of between at least 10% and no more than 40%. The “ratio of surface area” in this context refers to a ratio of surface area occupied by the cavities 16 on the entire surface area of the outer circumferential surface of a roller.

Turning to FIG. 1, since the roller outer circumferential surface for the rollers 4, 5 is described by a curved surface formed by the aforementioned solid of revolution, the surface area of a portion of the roller outer circumferential surface for the rollers 4, which is occupied by the cavities 16 (FIG. 5), can be determined as follows: for example, the surface area of a portion, which is occupied by the cavities (FIG. 5) within a given circumferential segment of the roller outer circumferential surface for a roller 4, 5—when viewed in a plan view thereof through an imaging device such as a microscope—is measured. Then, the same roller 4, 5 is rotated about an axis thereof relative to the imaging device to measure the surface area of a portion, which is occupied by the cavities 16 (FIG. 5) within an additional circumferential segment of the roller outer circumferential surface of that roller 4, 5—when viewed in a plan view thereof. Now, the same roller 4, 5 is rotated about an axis thereof to likewise measure the surface area of successive portions of the roller outer circumferential surface for that roller 4, 5, which are occupied by the cavities 16 (FIG. 5), to calculate and use a sum of the measurements obtained over the entire roller outer circumferential surface for that roller 4, 5 as the surface area for the cavities 16 (FIG. 5). Note that, as an alternative, the imaging device can be successively rotated relative to the roller outer circumferential surface in order to measure the surface area for the cavities. By selecting the upper limit for the ratio of surface area occupied by the cavities 16 shown in FIG. 5 to be 40%, the DLC film 9 can keep its durability and can thereby prevent delamination of the superficial layer 9c from the DLC film 9. Further, by selecting the lower limit for the ratio of surface area occupied by the cavities 16 to be 10%, it is ensured that the lubricating agent can be held in the cavities 16. More preferably, the upper limit for the ratio of surface area occupied by the cavities 16 is between 35 and 40%, while the lower limit for the ratio of surface area occupied by the cavities 16 is between 10 and 20%.

In addition, the cavities 16 have a size L of 10 to 100 μm when viewed in a plan view thereof. In order to measure the size L of the cavities 16 when viewed in a plan view thereof, a roller is successively rotated about an axis thereof relative to an imaging device as in the aforementioned procedure for measuring the surface area for the cavities 16. The size L of each cavity 16 when viewed in a plan view thereof can be determined as the maximum distance measured through, for example. an imaging device, between the farthest points P1, P2 on the outer edge of the same cavity 16. The size L of the cavities 16 of 10 μm or less is associated with a risk of the cavities 16 exhibiting an insufficient force with which to hold the lubricating agent. The size L of the cavities 16 of 100 μm or more is associated with a risk of the occurrence of microdelamination in the roller outer circumferential surface.

As can be seen in FIGS. 3A and 3B, a process for producing the DLC film includes the sequential steps of depositing the DLC film (FIG. 3A) and forming the cavities 16 in the superficial layer 9c of the DLC film (FIG. 3B).

<Step for Depositing DLC Film>

After a surface preparation step, the DLC film 9 is deposited on the roller circumferential surface for the rollers 4, 5. Examples of a film deposition process that can be applied for the DLC film 9 include CVD (Chemical Vapor Deposition) processes such as thermal CVD and plasma CVD as well as PVD (Physical Vapor Deposition) processes such as a vacuum deposition process, ion plating, a sputtering process, a laser ablation process, ion beam deposition, and an ion implantation process.

As illustrated in FIG. 3A, the film deposition step involves: depositing the metal layer 9a, which contains chromium Cr as a principal component thereof, directly on the roller outer circumferential surface for the rollers 4, 5; depositing the intermediate layer 9b, which contains DLC as a principal component thereof, on the metal layer 9a; and depositing the superficial layer 9c, which contains DLC as a principal component thereof, on the intermediate layer 9b.

The content ratio of Cr decreases and the content ratio of DLC in the intermediate layer 9b increases, in a continuous manner or stepwise manner from a side adjacent to the metal layer 9a towards a side adjacent to the superficial layer 9c. By way of example, in case of plasma CVD, such an intermediate layer 9b can be formed by gradually changing, for example, the concentration of feedstock gas introduced. The use of the aforementioned trilayered structure as a configuration of the DLC film 9 in the instant embodiment helps avoid abrupt changes in physical properties (e.g., a hardness and an elastic modulus.)

Compared to those employing W, Ti, Si, Al, and/or the like, the metal layer 9a containing Cr has an advantageous compatibility with and exhibits excellent adhesion to a substrate or base material which is formed of a cemented carbide material or a ferrous material. Preferably, the content ratio of Cr in the metal layer 9a decreases from a side adjacent to the roller surface towards a side adjacent to the intermediate layer 9b. In this way, it exhibits excellent adhesion on both sides against the roller surface and the intermediate layer 9b, respectively.

<Step for Forming Cavities>

After the film deposition step, the cavities 16 are formed in the superficial layer 9a, as shown in FIGS. 3B, 4, and 5. The cavities 16 include a void of soft DLC present in the superficial layer 9c and having a film hardness lower than those of the additional layers or remaining layers composed of the metal layer 9a and the intermediate layer 9b. After the DLC film is deposited, the cavities 16 can be formed with ease by removing the soft DLC scattered at the top of the superficial layer 9c in, for example, a lapping process.

<Test and Test Results>

After a DLC film was deposited on the outer circumferential surface of each of several test pieces having a cylindrical shape, multiple cavities were formed in a superficial layer of the DLC film by removing the soft DLC scattered at the top of the superficial layer in a lapping process.

The following conditions were applied to the test:

Test Piece: a cylindrical shape having a size of 20 mm(inner diameter)×40 mm(outer diameter)×12 mm(width) and made from high carbon chromium bearing steel.

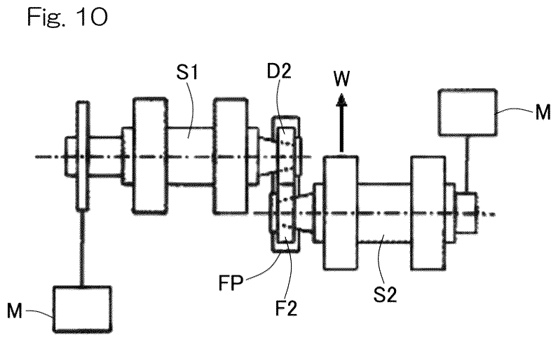

Two-cylinder Test Machine: as generally illustrated in FIG. 10, it had two mutually parallel rotary shafts S1, S2, with one S1 of the rotary shafts being provided thereon with a test piece D2 treated with the DLC film and the other S2 of the rotary shafts being provided thereon with a non-treated test piece F2 for comparison. The rotary shafts S1, S2 were able to be driven into rotation with respective motors M. Here, the test was performed by selecting values simulating the in-field use conditions of a main shaft bearing for a wind turbine generator, for a load and a rotational speed applied to the test pieces D2, F2. A felt pad FP impregnated with lubricant oil was used as a lubricating mechanism to feed oil and was placed directly under each of the test pieces D2, F2. Note that pure, low-viscosity oil was used as a lubricating agent to reproduce oil-depleted conditions.

At the end of each test, the surface state of DLC in the DLC film was examined under an optical microscope. In this way, the delamination resistances and the lubricating agent holding forces of DLC films prepared according to different sets of conditions were assessed. At the end of each test, cavities 16 (FIG. 5) in the surface were assessed with respect to a lubricating agent holding force: they were deemed to have no issue, if they exhibited an interference color IF (FIG. 5) representing the presence of a lubricating agent in a lubricated environment.

TABLE 1

| | Cavity Feature Size (μm) | | | | | | |
|---|---|---|---|---|---|---|---|
| | ≤10 | 30 | 50 | 70 | 90 | 100 | ≥110 |
| (i) Delamination | Good | Good | Good | Good | Good | Poor | Bad |
| Resistance | | | | | | | |
| (ii) Lubricating | Poor | Good | Good | Good | Good | Good | Good |
| Agent Holding | | | | | | | |
| Force | | | | | | | |

For (i) delamination resistance, Good indicates no delamination, Poor indicates the occurrence of microdelamination, and Bad indicates the presence of delamination. For (ii) a lubricating agent holding force, Good indicates no issue in terms of a holding force, and Poor indicates an insufficient holding force.

The test results summarized in Table 1 show that delamination developed in a DLC film at around the sizes of the cavities of around 100 μm.

As it is generally favorable to keep down the ratio of surface area occupied by the cavities to a certain degree from the viewpoint of the durability of the DLC film, an upper limit for the ratio of surface area occupied by the cavities was selected to be 40%. Further, a lower limit for the ratio of surface area occupied by the cavities was selected to be 10%, from the viewpoint of ensuring that a lubricating agent is held in the cavities.

### Effects and Benefits

The cavities 16 provided in the superficial layer 9c of the DLC film 9 with a size of between more than 10 μm and less than 100 μm in the self-aligning roller bearing 1 that has been discussed thus far can serve as so-called, oil reservoir dimples in which a lubricating agent is held, to thereby help improve the ability of the lubricating agent to form oil films and, therefore, help achieve an improved lubricating performance in a less lubricated situation or a lightly lubricated environment. In addition, by selecting the ratio of surface area occupied by the cavities 16 to be 40% or less, the DLC film 9 can keep its durability and can thereby prevent delamination of the superficial layer 9c from the DLC film 9.

It is possible to form the cavities 16 with ease by removing soft DLC present at the top of the superficial layer 9c in, for example, a lapping process. In this way, the cavities 16 can be formed without changing the deposition conditions for the DLC film itself, thereby preventing possible deteriorations in the properties of the DLC film 9. Furthermore, the cavities 16 can be formed without using fine particles provided specifically for this purpose as in a shot peening process, thereby enabling the manufacturing cost to be reduced.

The DLC film 9 has a trilayered structure of the metal layer 9a or a layer of a metal, a mixed layer of the metal and DLC as the intermediate layer 9b, and the superficial layer 9c, in the stated order starting from a side adjacent to a base material of the rollers 4, 5. For this reason, it is possible to avoid abrupt changes in the physical properties such as a hardness and an elastic modulus within the DLC film 9, thereby improving the adhesion of the DLC film 9 to the rollers 4, 5.

### Further Embodiments

Further embodiments will be described below. In the following discussion, features corresponding to those discussed in conjunction with preceding embodiment(s) will be indicated with the same reference symbols therefrom and will not be discussed again to avoid redundancy. Where only a subset of features of an embodiment are discussed, the rest of the features should be construed as the same as the previously discussed features unless otherwise stated. Identical features produce identical effects and benefits. In addition to particularly discussed combinations of features in each of the embodiments, the embodiments themselves may also be partially combined with each other unless such combinations are inoperable.

### Second Embodiment

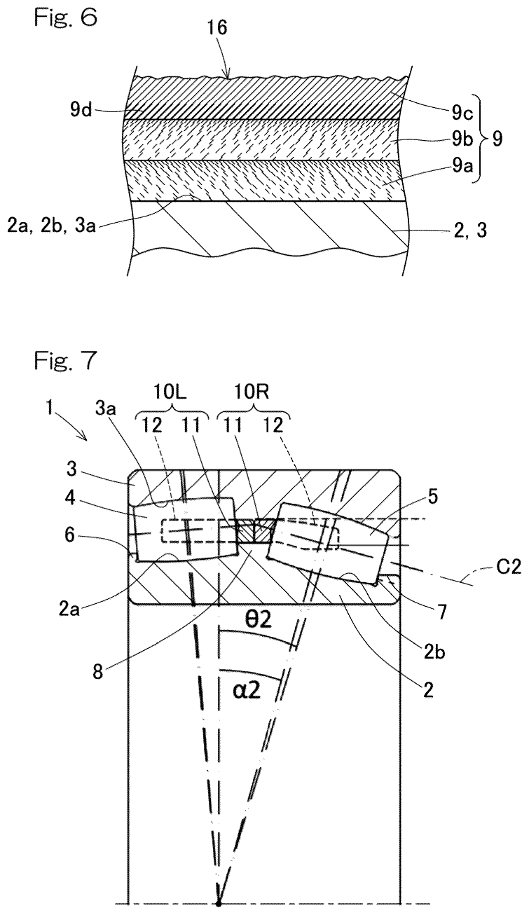

Turning to FIG. 6, in addition to the aforementioned DLC film provided with the cavities in the roller outer circumferential surface, a DLC film 9 may be present on at least one of the raceway surface 2a of the inner ring, the raceway surface 2b of the inner ring, or the raceway surface 3a of the outer ring, with cavities 16 provided in a superficial layer 9c of the DLC film 9 to hold the lubricating agent. The raceway surface or raceway surfaces have a ratio of surface area occupied by the cavities 16 of 40% or less. The cavities 16 have a size of 10 to 100 μm when viewed in a plan view thereof.

The cavities 16 provided in the superficial layer 9c of the DLC film 9 with a size of 10 to 100 μm on respective one(s) of the raceway surfaces 2a, 2b, 3a according to this configuration can also serve as so-called, oil reservoir dimples in which the lubricating agent is held. Thus, a further improved lubricating performance can be achieved thanks to the combined effect with the lubricant agent held in the cavities provided in the DLC film on the rollers.

### Third Embodiment

While each of the preceding embodiments is directed to an example application involving a self-aligning roller bearing of a left and right symmetrical design, a self-aligning roller bearing of a left and right asymmetrical design, e.g., a self-aligning roller bearing 1 with left and right rows having different contact angles θ1, θ2, such as the one shown in FIG. 7, may be used. A DLC film may be provided in the roller outer circumferential surface for rollers 4, 5 in the self-aligning roller bearing 1 of a left and right asymmetrical design. In addition, a DLC film may be provided on at least one of the raceway surface 2a of the inner ring 2, the raceway surface 2b of the inner ring 2, or the raceway surface 3a of the outer ring 3.

Although not shown in the figures, a DLC film may be provided on a roller outer circumferential surface in a cylindrical roller bearing or a tapered roller bearing. In addition, a DLC film may be provided on at least one of a raceway surface of an inner ring or a raceway surface of an outer ring of the same.

Dry lapping may be employed as the lapping process in which the cavities are formed.

In one reference example proposed, cavities may only be provided in the superficial layer of the DLC film present on at least one of the raceway surface of the inner ring or the raceway surface of the outer ring. The raceway surface or raceway surfaces have a ratio of surface area occupied by the cavities of 40% or less. The cavities have a size of 10 to 100 μm when viewed in a plan view thereof.

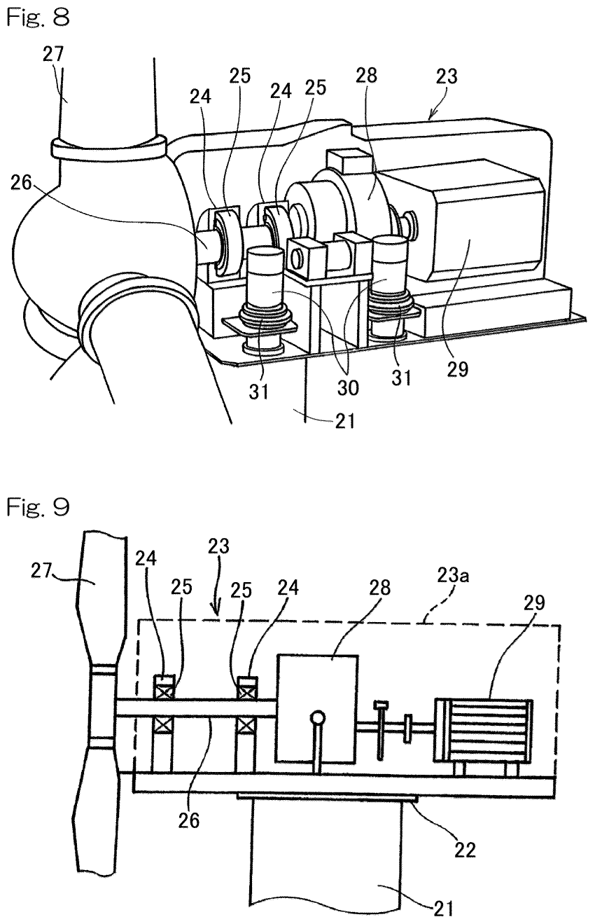

FIGS. 8 and 9 show an example main shaft support assembly for a wind turbine generator. A casing 23a of a nacelle 23 is disposed on a support base 21 with a slewing bearing 22 (FIG. 9) interposed therebetween to allow a slewing motion of the casing 23a in the horizontal. Within the casing 23a of the nacelle 23, a main shaft 26 is rotatably disposed on a main shaft support bearing 25 located in a bearing housing 24. Rotating blades 27 are attached to a portion of the main shaft 26 which is situated outside of the casing 23a. A self-aligning roller bearing 1 in any one of the embodiments can be used as the main shaft support bearing 25.

The other end of the main shaft 26 is coupled to a gear box 28 whose output shaft connects to a rotary shaft of a generator 29. The nacelle 23 can be slewed by a given angle using slewing motors 30 and through speed reducers 31. While two main shaft support bearings 25 are arranged side by side in the illustrated example, a single main shaft support bearing 25 can alternatively be provided.

The self-aligning roller bearing, cylindrical roller bearing, and tapered roller bearing in any one of the embodiments as well as the roller bearing and ball bearing in the one reference example proposed can also be used in applications other than a wind turbine generator, including, for example, industrial machines, machine tools, and robots.

While preferred embodiments have thus been discussed with reference to the drawings, various additions, modifications, and omissions may be made therein without departing from the principle of the present invention. Accordingly, such additions, modifications, and omissions are also construed to be encompassed within the scope of the present invention.

### REFERENCE SYMBOLS

1 self-aligning roller bearing
2 inner ring
2a, 2b . . . raceway surface
3 . . . outer ring
3a . . . raceway surface
4, 5 . . . roller
9 . . . DLC film
9a . . . metal layer
9b . . . intermediate layer
9c . . . superficial layer
10L, 10R . . . cage
16 . . . cavity
26 . . . main shaft

What is claimed is:

1. A roller bearing comprising:
inner and outer rings;
rollers interposed between raceway surfaces of the inner and outer rings and having a roller outer circumferential surface;
a cage retaining the rollers; and
a DLC film on the roller outer circumferential surface, the DLC film including a superficial layer having cavities provided therein to hold a lubricating agent, the rollers having a ratio of surface area occupied by the cavities of 40% or less, and the cavities having a size of 10 to 100 μm when viewed in a plan view thereof.

2. The roller bearing as claimed in claim 1, wherein the DLC film has a multilayered structure in which the superficial layer is layered on an additional layer, and the cavities comprise a void of soft DLC present in the superficial layer and having a film hardness lower than that of the additional layer.

3. The roller bearing as claimed in claim 2, wherein the DLC film has a trilayered structure of a metal layer or a layer of a metal, a mixed layer of the metal and DLC as an intermediate layer, and the superficial layer, in the stated order starting from a side adjacent to a base material of the rollers.

4. The roller bearing as claimed in claim 1, further comprising:
a DLC film on at least one of the raceway surface of the inner ring or the raceway surface of the outer ring, the DLC film including a superficial layer having cavities provided therein to hold the lubricating agent, the raceway surface or raceway surfaces having a ratio of surface area occupied by the cavities of 40% or less, and the cavities having a size of 10 to 100 μm when viewed in a plan view thereof.

5. The roller bearing as claimed in claim 1, wherein the roller bearing is a self-aligning roller bearing configured to support a main shaft of a wind turbine generator.
